(19) United States
(12) Patent Application Publication
(10) Pub. No.: US 2015/0340839 A1
(43) Pub. Date: Nov. 26, 2015

(54) LASER MODULE CONTROL CIRCUIT

(71) Applicant: CHANGZHOU HUADA KEJIE OPTO-ELECTRO INSTRUMENT CO., LTD., Changzhou (CN)

(72) Inventors: Ou Zhang, Changzhou (CN); Hongjun Zhu, Changzhou (CN); Dongdong Peng, Changzhou (CN); Qing Niu, Changzhou (CN)

(21) Appl. No.: 14/427,042

(22) PCT Filed: Jul. 15, 2013
(86) PCT No.: PCT/CN2013/000850

§ 371 Date: Aug. 3, 2015

(30) Foreign Application Priority Data
Sep. 13, 2012 (CN) 201220466142.3

(51) Int. Cl. H01S 5/042

(52) U.S. Cl. CPC H01S 5/042

(57) ABSTRACT

A laser module control circuit comprises a laser module circuit, wherein the laser module circuit is connected in parallel with a first control sub-circuit and a second control sub-circuit, with a first triode arranged in the first control sub-circuit and a second triode arranged in the second control sub-circuit, while the collector electrode of the first and second triodes is connected with the laser module circuit. The base electrode thereof is connected with the CPU, and the emitter electrode thereof is connected to the ground.

### FIELD OF THE INVENTION

The present invention relates to a control circuit, in particular, a laser module control circuit.

### BACKGROUND

A specific level of laser safety is required for laser apparatuses. For example, in a laser level, the laser output power (in a still or rotation situation) should be lower than the laser safety level II.

In the prior art, a single control triode is used to modulate the laser output power lower than the laser safety level by PWM modulation. As shown in FIG. 1, the laser module driving circuit in the prior art used a single triode to control the laser module. When the speed is greater than 5 RPM with a high level signal of about 3V input into CPU-A, the laser module is in a conducting state (i.e. the laser output of 2 mW). When the speed is less than 5 RPM with a square wave in the form of PWM (with a 50% duty ratio) inputting into CPU-A, the laser module is modulated by PWM into a conducting state (i.e. the laser module outputs power at an average power of 1 mW). When the rotation speed is 0 RPM, the instantaneous power of the laser module is far greater than the laser safety level of 1 mW.

However, the forementioned prior art possesses the following disadvantages:

(1) When lasers are applied in PWM modulation, the instantaneous power still goes beyond the laser safety level, and the impulsive control may cause damage to the service life of the laser tube;

(2) When the single control triode fails (such as CE short cut), the laser output power will go beyond the laser safety level II;

(3) When the laser apparatus is rotating, the usage of PWM modulation leads to breakpoints of the laser light, where the laser detectors are unable to detect and receive.

Therefore, a laser module control circuit is needed to overcome the disadvantages described above.

### SUMMARY OF THE INVENTION

To solve the problem, the objective of the present invention is to provide a laser module control circuit to overcome the disadvantages described above.

To implement the above objective, the present invention provides a laser module control circuit, which comprises a laser module circuit, wherein the laser module circuit is connected in parallel with a first control sub-circuit and a second control sub-circuit, with a first triode arranged in the first control sub-circuit and a second triode arranged in the second control sub-circuit, while the collector electrode of the first and second triodes is connected with the laser module circuit. The base electrode thereof is connected with the CPU, and the emitter electrode thereof is connected to the ground.

Preferably, the laser module control circuit in the present invention further comprises a closed-loop detective circuit. The closed-loop detective circuit is configured to conduct the first triode and cut-off the second triode when the laser stands still, or conduct the first and second triodes when the laser rotates.

Preferably, the first and second triodes in the present invention are NPN transistors.

Preferably, biasing resistors are arranged between the base electrode and the CPU.

There is a special improvement on the laser module control circuit in the invention. The light output power of the laser tube is controlled by controlling the full conducted current of the triodes with two NPN transistors, thereby achieving better safety performance.

### BRIEF DESCRIPTION OF THE DRAWINGS

FIG. 1 schematically shows the laser module control circuit in the prior art;

FIG. 2 shows the laser module control circuit in a preferred embodiment of the invention.

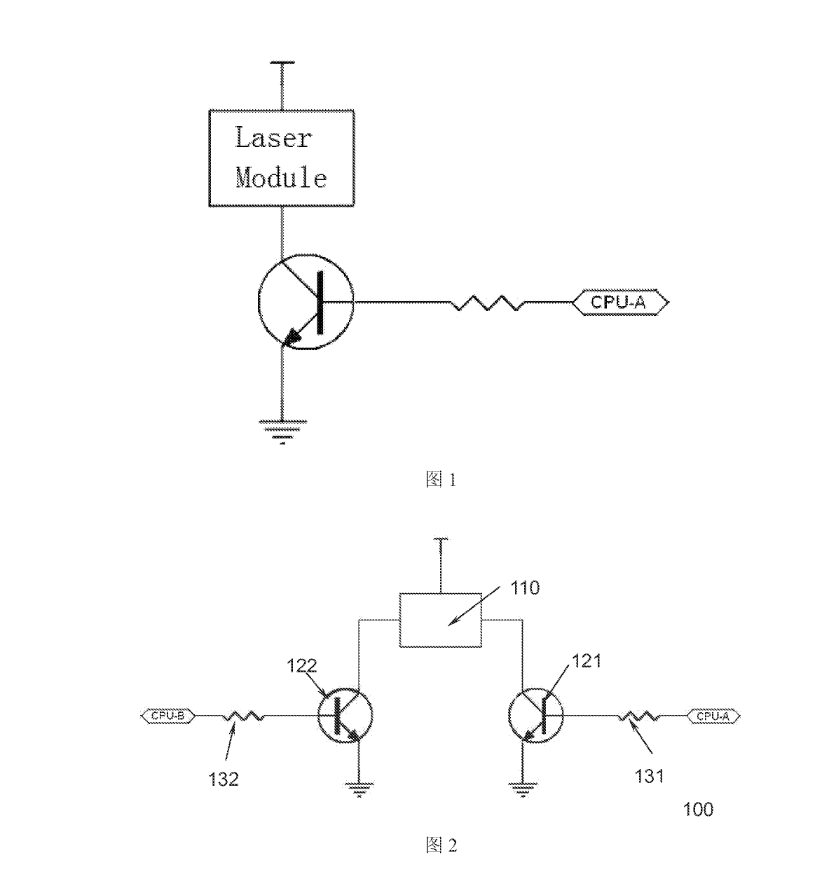

### DETAILED DESCRIPTION OF THE INVENTION

The advantages of the present invention will be detailed and described in reference to the drawings and the embodiments as follows.

As shown in FIG. 2, in a preferred embodiment of the invention, a laser module control circuit 100, which is arranged in a laser level, comprises a laser module circuit 110, which is connected in parallel with a first control sub-circuit and a second control sub-circuit. The first control sub-circuit comprises a first NPN transistor 121 with its collector electrode connected with the laser module circuit 110, its base electrode connected with CPU-A through a first biasing resistor 131, and its emitter electrode connected to ground. Correspondingly, the second control sub-circuit comprises a second NPN transistor 122 with its collector electrode connected with the laser module circuit 110, its base electrode connected with CPU-B through a second biasing resistor 132, and its emitter electrode connected to ground.

In the laser module control circuit 100, a closed-loop detective circuit (not depicted) is further arranged. The closed-loop detective circuit is configured to conduct the first NPN transistor 121 and cut-off the second transistor 122 when the laser level device stands still, or conduct the first NPN transistor 121 and the second transistor 122 when the laser rotates.

The laser module circuit 110 can achieve two switches during constant power of the laser module by controlling the logical relationship between the conduction and cutoff of two triodes based on the arrangement described above. The logical relationship is shown as follows:

| | CPU- | CPU- | First NPN | Second NPN | Laser | |
|---|---|---|---|---|---|---|
| No. | A | B | Transistor | Transistor | Power | Rev. |
| 1 | 0 | 0 | Cut-off | Cut-off | 0 mW | <5 RPM |
| 2 | 0 | 1 | Cut-off | Conduction | <0.2 mW | <5 RPM |
| 3 | 1 | 0 | Conduction | Cut-off | 1 mW | <5 RPM |
| 4 | 1 | 1 | Conduction | Conduction | 2 mW | >5 RPM |

It can learn, based on the table above, that only when two NPN transistors have failed and conducted simultaneously will the laser output power go beyond the laser safety level of 1 mW. Therefore, the laser output's probability of exceeding the laser safety level will be greatly reduced. Even if the two NPN transistors fail simultaneously, causing the laser output power to go beyond the safety level, the rotational speed will now be more than 5 RPM. In this way, the time of the output laser staying on human eyes will be substantially reduced compared to the prior art, so therefore the damage to the human eyes will be greatly reduced.

It should be noted that the embodiments of the present invention has a preferred implementation, and will not limit the present invention in any form, and any technician skilled in the field may change or modify to equivalent effective embodiments by using the above-described technique. Whenever the contents do not depart from the technical proposal in the present invention, any revision or equivalent change and modification of the above embodiments according to the technical substance of the present invention are all in the scope of the technical proposal in the present invention.

1. A laser module control circuit comprises a laser module circuit, wherein the laser module circuit is connected in parallel with a first control sub-circuit and a second control sub-circuit, with a first triode arranged in the first control sub-circuit and a second triode arranged in the second control sub-circuit, while the collector electrode of the first and second triodes is connected with the laser module circuit, the base electrode thereof is connected with the CPU, and the emitter electrode thereof is connected to the ground.

2. The laser module control circuit according to claim 1, wherein the laser module control circuit further comprises a closed-loop detective circuit.

3. The laser module control circuit according to claim 2, wherein the closed-loop detective circuit is configured to conduct the first triode and cut-off the second triode when the laser stands still, or conduct the first and second triodes when the laser rotates.

4. The laser module control circuit according to claim 1, wherein the first and second triodes are NPN transistors.

5. The laser module control circuit according to claim 1, wherein biasing resistors are arranged between the base electrode and CPU.
